(19) United States
(12) Patent Application Publication
(10) Pub. No.: US 2014/0055948 A1
(43) Pub. Date: Feb. 27, 2014

(54) ELECTRONIC DEVICE AND HOUSING

(71) Applicants: FU TAI HUA INDUSTRY (SHENZHEN) CO., LTD., Shenzhen (CN); HON HAI PRECISION INDUSTRY CO., LTD., New Taipei (TW)

(72) Inventor: Hong-Wei ZHU, Shenzhen (CN)

(73) Assignees: HON HAI PRECISION INDUSTRY CO., LTD., New Taipei (TW); Fu Tai Hua Industry (Shenzhen) Co., Ltd., Shenzhen (CN)

(21) Appl. No.: 13/686,932

(22) Filed: Nov. 28, 2012

(30) Foreign Application Priority Data
Aug. 24, 2012 (CN) 2012103037992

(51) Int. Cl. H05K 5/03

(52) U.S. Cl. CPC H05K 5/03
USPC 361/679.55

(57) ABSTRACT

A housing for an electronic device includes a front frame, a back cover, and a connecting assembly. The connecting assembly includes a sliding member slidably connected to the back cover, a driving member movably connected to the back cover, a first connecting member formed on the front frame, and a second connecting member securely connected to the sliding member. The driving member is used to drive the sliding member to slide. The second connecting member is engageable with the first connecting member. The sliding member is slidable between a first position where the first connecting member is engaged with the second connecting member, thereby connecting the first frame to the back cover, and a second position where the first connecting member disengages from the second connecting member.

### BACKGROUND

1. Technical Field

The present disclosure relates to an electronic device and a housing of the electronic device.

2. Description of Related Art

Many electronic devices, such as cellular phones and tablet computers, include a front frame and a back cover. Many connecting mechanisms have been proposed to connect the front frame and the back cover together. However a new type of connecting mechanism for connecting the front frame and the back cover together is still needed.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an electronic device according to one embodiment.

FIG. 2 is similar to FIG. 1, but viewed from a different viewpoint.

FIG. 3 is an isometric exploded view of the electronic device of FIG. 1.

FIG. 4 is an enlarged view of the portion IV of FIG. 3.

FIG. 5 is a cross-sectional view of the electronic device of FIG. 1, showing a first connecting member to be engaged with a second connecting member.

FIG. 6 is similar to FIG. 5, but showing the first connecting member to be disengaged from the second connecting member.

### DETAILED DESCRIPTION

Embodiments of the present disclosure will be described with reference to the accompanying drawings.

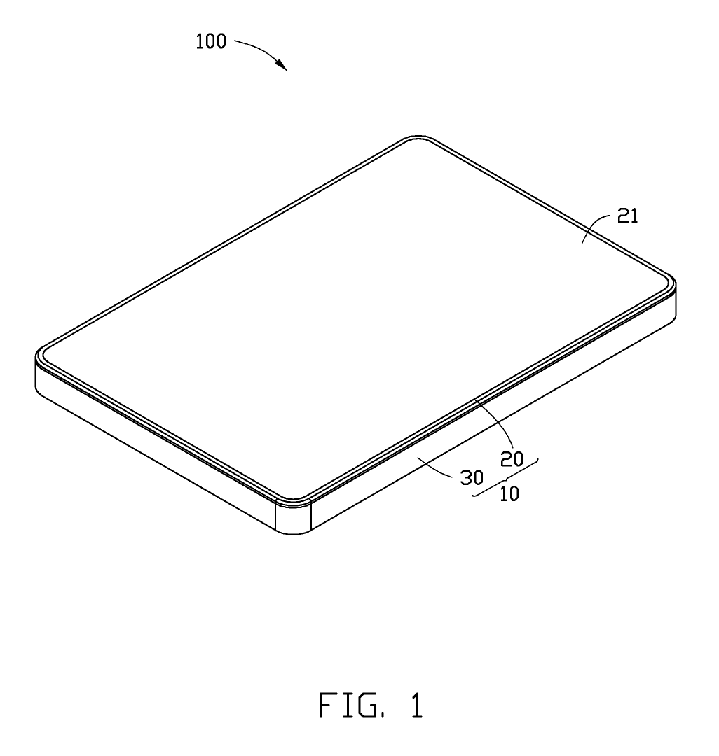

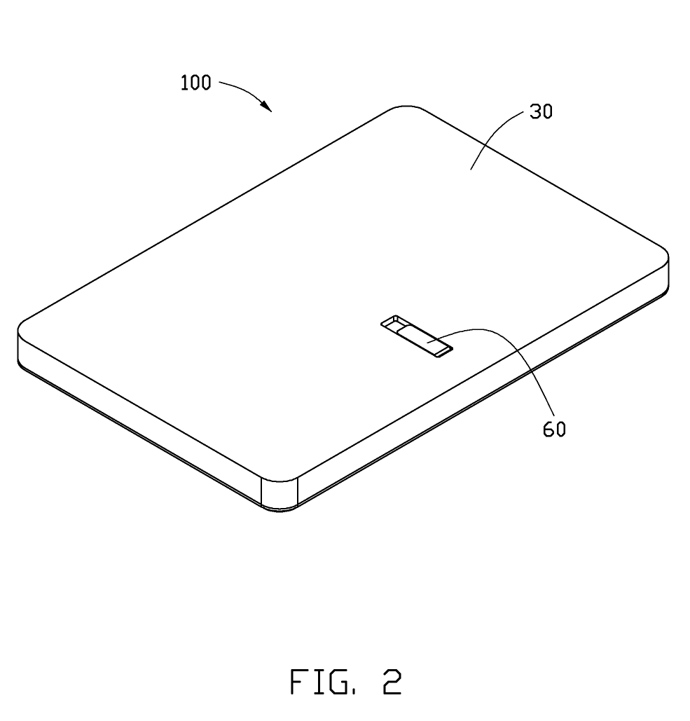

FIGS. 1 and 2 show an electronic device 100 according to one embodiment. The electronic device 100 includes a housing 10. The housing 10 includes a front frame 20 and back cover 30. A display panel 21 is coupled to the front frame 20. In the embodiment, the electronic device 100 is a tablet computer.

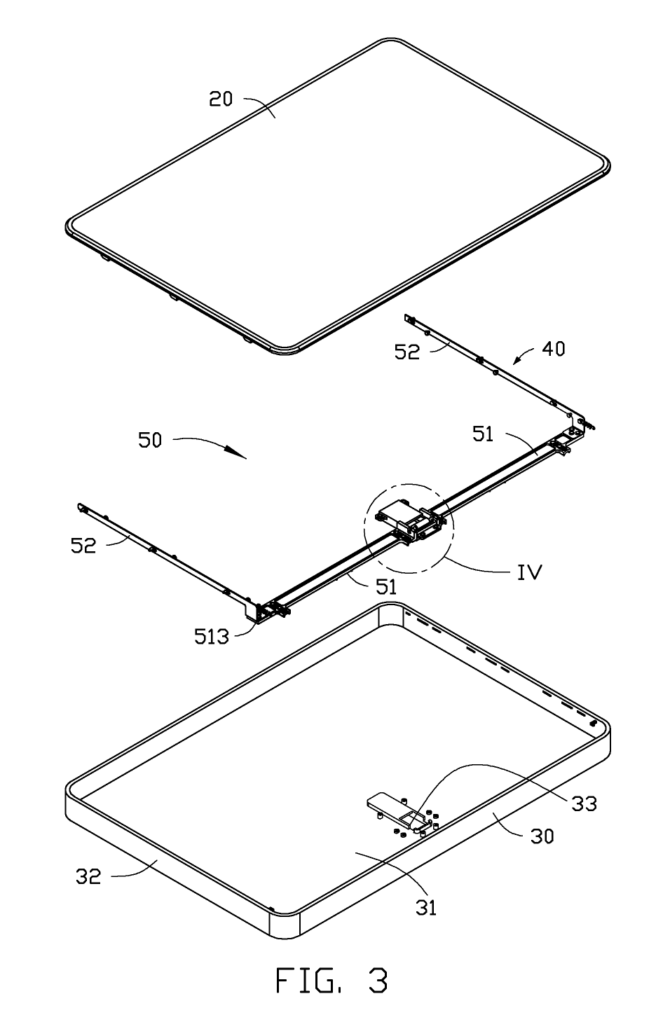

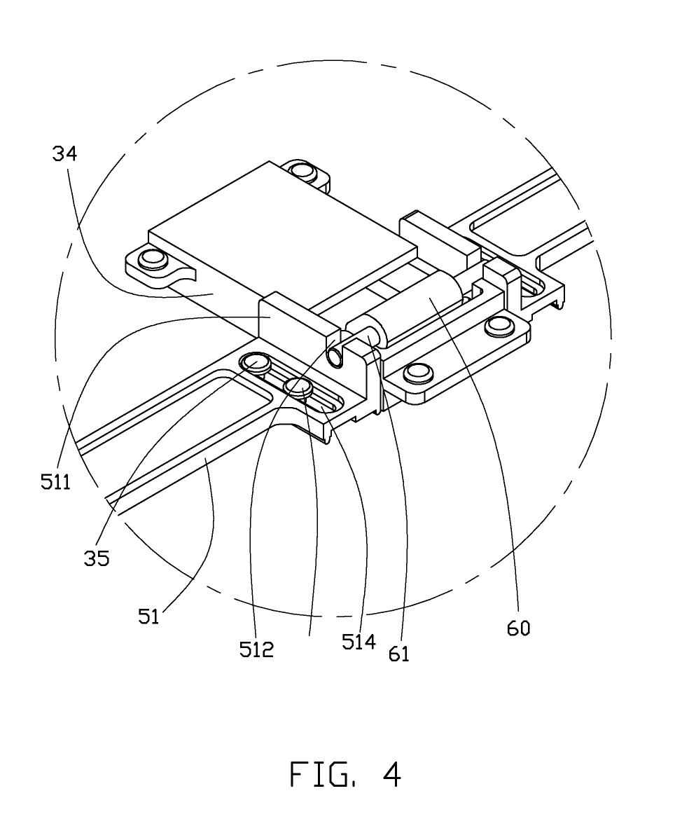

Referring to FIGS. 3-6, the front frame 20 and the back cover 30 are detachably coupled together via a connecting assembly 40. The connecting assembly 40 includes a sliding member 50, a driving member 60, several first connecting members 70, and several second connecting members 80. The sliding member 50 is slidably connected to an inner surface of the back cover 30. In the embodiment, the sliding member 50 includes two sliding bars 51 sliding connected to the bottom 31 of the back cover 30, and two side arms 52 slidably connected to opposite sidewalls 32 of the back cover 30.

Each sliding bars 51 defines a groove 514, and the back cover 30 includes several shafts 35 protruding from the bottom 31. Some shafts 35 pass through the groove 514 and are fixed to the bottom 31. When pushed, each sliding bar 51 is guided by the shafts 35 and slides with respect to the bottom 31.

Each side arm 52 is securely coupled to an end 513 of one sliding bars 51. Each side arm 52 is slidably connected to one sidewall 32 in the same manner as the sliding bars 51. Each side arm 52 includes several second connecting members 80. In the embodiment, the second connecting members 80 are posts.

In the embodiment, the back cover 30 defines an opening 33 in the bottom 31 and includes two protruding walls 34 extending along opposite edges of the opening 33. An axle (not shown) passes through the driving member 60, with its opposite ends fixed to the protruding walls 34, thereby rotatably connecting the driving member 60 to the back cover 30. The driving member 60 further includes a shaft 61 at an end. Each end of the shaft 61 is movably received in a hole 512 defined in a wall 511 at an end of one sliding bar 51. When a user rotates the driving member 60, the shaft 61 pushes the sliding bars 51 to slide.

The first connecting members 70 are hooks securely coupled to the inner surface of the front frame 20 and arranged along opposite edges of the front frame 20.

In the embodiment, the electronic device 100 further includes two resilient members 90. In the embodiment the two resilient members 90 are coil springs. The opposite ends of each resilient member 90 are fixed to the sliding member 50. The resilient members 90 are used to apply a push force to the sliding member 50.

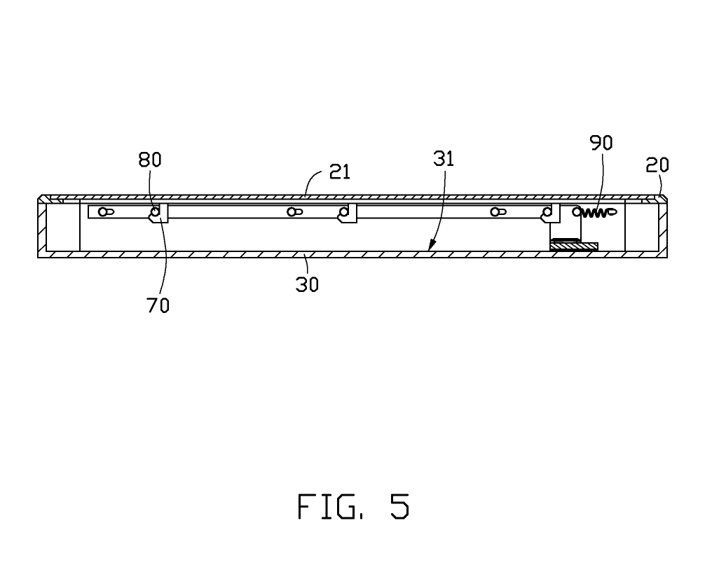

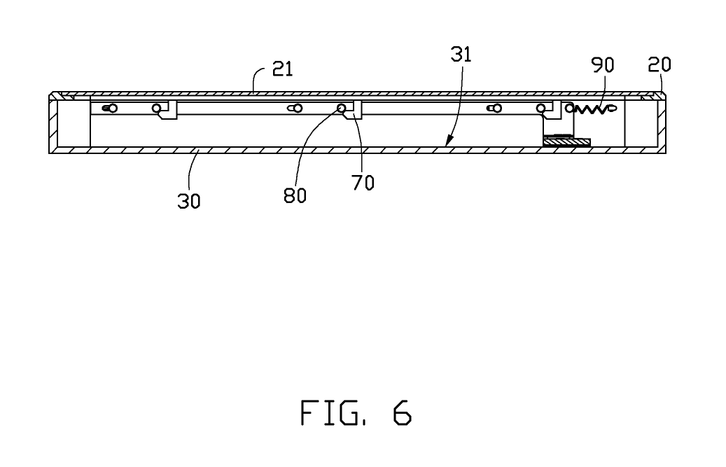

The siding member 50 is slidable between a first, locked position (FIG. 5) where the first connecting members 70 are engaged with the second connecting members 80, thereby connecting the first frame 20 to the back cover 30, and a second, unlocked position (FIG. 6) where the first connecting member 70 is disengaged from the second connecting member 80, allowing a user to detach the front frame 20 from the back cover 30.

While various embodiments have been described and illustrated, the disclosure is not to be construed as being limited thereto. Various modifications can be made to the embodiments by those skilled in the art without departing from the true spirit and scope of the present disclosure as defined by the appended claims.

What is claimed is:

1. A housing for an electronic device, comprising:
a front frame;
a back cover; and
a connecting assembly comprising:
a sliding member slidably mounted to the back cover;
a driving member movably connected to the back cover, the driving member being configured to drive the sliding member to slide;
a first connecting member formed on the front frame; and
a second connecting member securely connected to the sliding member, the second connecting member being engageable with the first connecting member;
wherein the sliding member is slidable between a first position where the first connecting member is engaged with the second connecting member, thereby connecting the first frame to the back cover, and a second position where the first connecting member is disengaged from the second connecting member.

2. The housing according to claim 1, wherein the first connecting member is a hook, and the second connecting member is a post.

3. The housing according to claim 1, wherein the driving member is rotatable with respect to the back cover and comprises a shaft, the sliding member defines two holes, opposite ends of the shaft are movably received in the two holes, and the shaft is configured to push the sliding member to slide when the driving member rotates.

4. The housing according to claim 1, further comprising a resilient member, wherein the opposite ends of the resilient member are securely connected to the back cover and the sliding member, the resilient member is configured to apply a pushing force to the sliding member, thereby retaining the sliding member in the first position.

5. The housing according to claim 4, wherein the resilient member is a coil spring.

6. An electronic device comprising:
a display panel;
a front frame configured to receive the display panel;
a back cover; and
a connecting assembly comprising:
a sliding member slidably mounted to the back cover;
a driving member movably connected to the back cover, the driving member being configured to drive the sliding member to slide;
a first connecting member formed on the front frame; and
a second connecting member securely connected to the sliding member, the second connecting member being engageable with the first connecting member;
wherein the sliding member is slidable between a first position where the first connecting member is engaged with the second connecting member, thereby connecting the first frame to the back cover, and a second position where the first connecting member is disengaged from the second connecting member.

7. The electronic device according to claim 6, wherein the first connecting member is a hook, and the second connecting member is a post.

8. The electronic device according to claim 6, wherein the driving member is rotatable with respect to the back cover and comprises a shaft, the sliding member defines two holes, opposite ends of the shaft are movably received in the two holes, and the shaft is configured to push the sliding member when the driving member rotates.

9. The electronic device according to claim 6, further comprising a resilient member, wherein the opposite ends of the resilient member are securely connected to the back cover and the sliding member, the resilient member is configured to apply a pushing force to the sliding member, thereby retaining the sliding member in the first position.

10. The housing according to claim 9, wherein the resilient member is a coil spring.
